(19) United States
(12) Patent Application Publication
(10) Pub. No.: US 2011/0006364 A1
(43) Pub. Date: Jan. 13, 2011

(54) SEMICONDUCTOR DEVICE

(75) Inventors: Syotaro ONO, Kanagawa-ken (JP); Wataru SAITO, Kanagawa-ken (JP); Munehisa YABUZAKI, Hyogo-ken (JP); Nana HATANO, Kanagawa-ken (JP); Miho WATANABE, Tokyo (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/831,981

(22) Filed: Jul. 7, 2010

(30) Foreign Application Priority Data
Jul. 8, 2009 (JP) 2009-162187

(51) Int. Cl. H01L 29/78

(52) U.S. Cl. 257/330; 257/E29.257

(57) ABSTRACT

According to one embodiment, a semiconductor device includes a first-conductivity-type semiconductor layer, a first and second-conductivity-type semiconductor pillar regions, a second and first-conductivity-type semiconductor regions, a first and second main electrodes, and a control electrode. Each of the first and second-conductivity-type pillar regions extends in a first direction and is alternately provided along a second direction generally perpendicular to the first direction. The second-conductivity-type semiconductor region is provided in a cell region and connected to the second-conductivity-type semiconductor pillar region. The first-conductivity-type semiconductor region is selectively provided in a surface of the second-conductivity-type semiconductor region. The first main electrode is connected to the first-conductivity-type semiconductor layer. The second main electrode is connected to the first and second-conductivity-type semiconductor region. The control electrode is configured to control a current path between the first-conductivity-type semiconductor region and the first-conductivity-type semiconductor pillar region.

### CROSS-REFERENCE TO RELATED APPLICATIONS

This application is based upon and claims the benefit of priority from the prior Japanese Patent Application No. 2009-162187, filed on Jul. 8, 2009; the entire contents of which are incorporated herein by reference.

### FIELD

Embodiments described herein relate generally to a semiconductor device.

### BACKGROUND

Power semiconductor elements (semiconductor devices) such as power MOSFET (metal oxide semiconductor field effect transistor) elements and IGBT (insulated gate bipolar transistor) elements are widely used in power conversion and control applications such as communication base stations, home electric appliances, communication devices, and vehicle-mounted motors. Recently, with a view to achieving smaller size, higher efficiency, and lower power consumption of power supply systems based on these semiconductor elements, power semiconductor elements with a super junction structure have been attracting attention.

In this power semiconductor element, pillar-shaped p-type layers and n-type layers are alternately buried in a semiconductor layer, and the amount of charge (amount of impurity) contained in each layer is equalized. Thus, a non-doped layer is artificially formed in the drift layer of this power semiconductor element. Consequently, this power semiconductor element maintains a high breakdown voltage, and achieves a low on-resistance beyond the material limit by passing a current through the highly doped n-type pillar region.

Such power semiconductor elements have a structure of preventing the depletion layer from reaching the dicing line under high voltage application. For instance, a field stop layer or high resistance layer is placed near the dicing line, or the width of the super junction structure is varied between the internal region of the chip and the neighborhood of the dicing line.

However, the recent market of power semiconductor elements requires a lineup providing a large amount of power semiconductor elements with different values of rated current, resistance and the like. A method for offering such a lineup is to produce a large amount of semiconductor elements corresponding to each size by separately applying a wafer process for the size.

However, in the process (wafer process) for forming semiconductor elements from a semiconductor wafer, once a super junction structure with a predetermined width is formed in a predetermined region of the semiconductor wafer, it is difficult to change the chip size in the middle of the wafer process.

This difficulty may be prevented by separately producing a large amount of chips for every chip size as described above. However, such a method leads to excess inventory (overstock) of chips with chip sizes not meeting market needs.

### BRIEF DESCRIPTION OF THE DRAWINGS

FIGS. 1A to 3B are principal views of a semiconductor device;

FIGS. 4A to 6C are principal views illustrating a manufacturing process of the semiconductor device;

FIGS. 7A to 8B are principal views of a semiconductor device; and

FIGS. 9A to 10B are principal views of a semiconductor device.

### DETAILED DESCRIPTION

In general, according to one embodiment, a semiconductor device includes a first-conductivity-type semiconductor layer, a first-conductivity-type semiconductor pillar region and a second-conductivity-type semiconductor pillar region, a second-conductivity-type semiconductor region, a first-conductivity-type semiconductor region, a first main electrode, a second main electrode, and a control electrode. Each of the first and second-conductivity-type pillar regions extends in a first direction and is alternately provided along a second direction generally perpendicular to the first direction entirely on a major surface of the first-conductivity-type semiconductor layer. The second-conductivity-type semiconductor region is provided on the second-conductivity-type semiconductor pillar region in a cell region and connected to the second-conductivity-type semiconductor pillar region. The first-conductivity-type semiconductor region is selectively provided in a surface of the second-conductivity-type semiconductor region. The first main electrode is connected to the first-conductivity-type semiconductor layer. The second main electrode is connected to the first-conductivity-type semiconductor region and the second-conductivity-type semiconductor region. The control electrode is configured to control a current path between the first-conductivity-type semiconductor region and the first-conductivity-type semiconductor pillar region. The cell region includes the first-conductivity-type semiconductor region, the second-conductivity-type semiconductor region, and the control electrode. The second-conductivity-type semiconductor pillar region extends from the cell region to a chip terminal portion surrounding the cell region, and is discontinued in an end region of the chip terminal portion.

Embodiments of the invention will now be described with reference to the drawings.

### First Embodiment

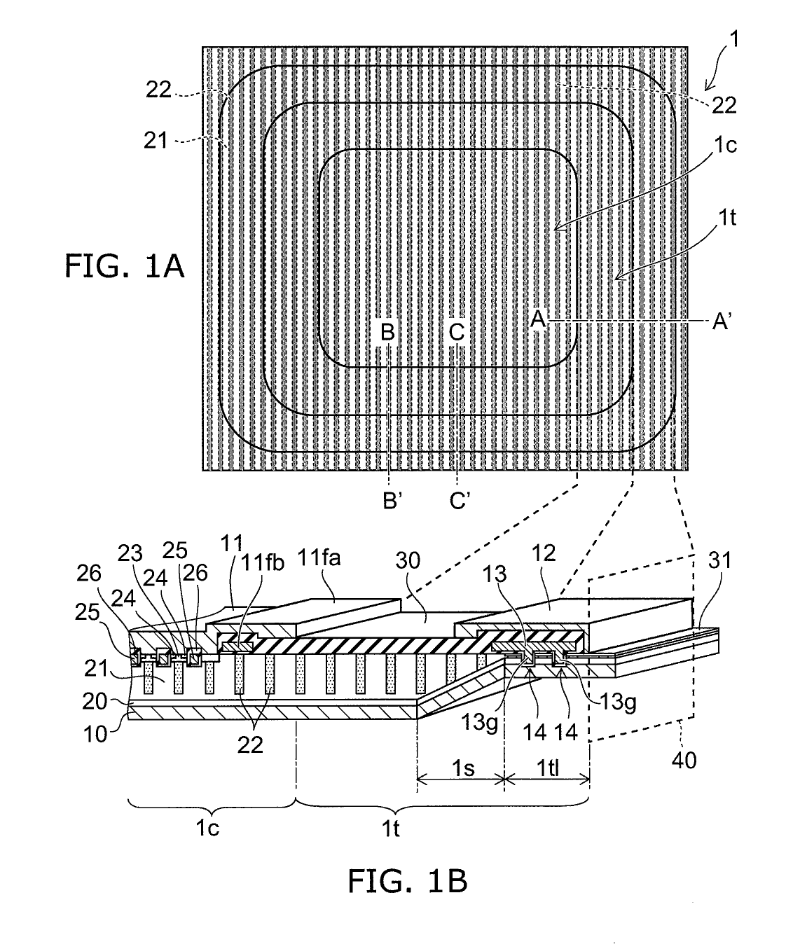

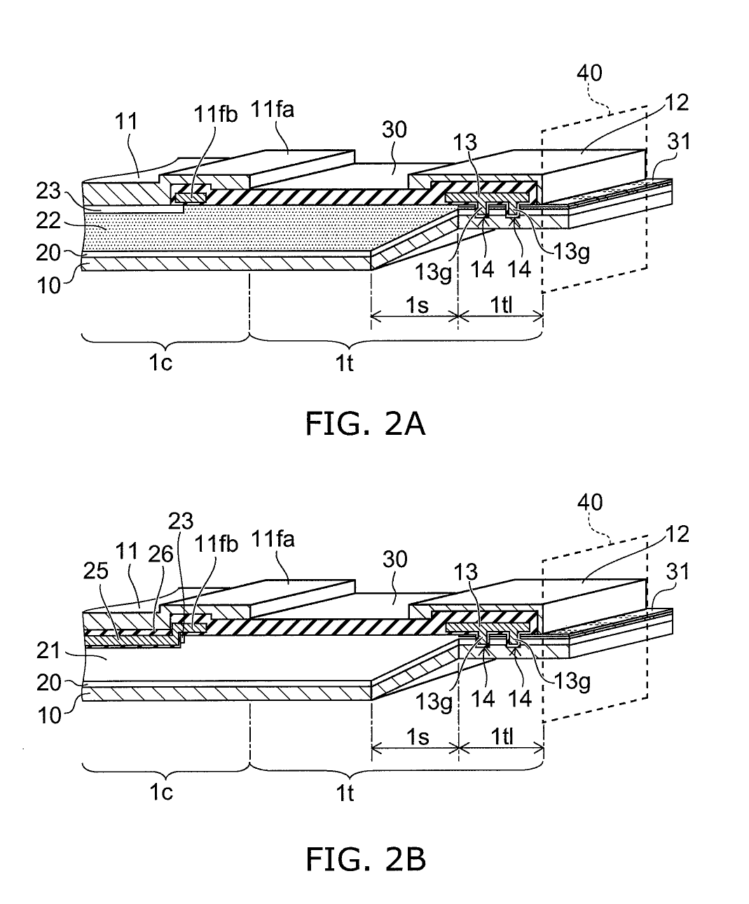

FIGS. 1A to 3B are principal views of a semiconductor device. Here, FIG. 1A is a principal plan view of the semiconductor device, and FIG. 1B shows an A-A′ perspective cross section of FIG. 1A. FIG. 2A shows a B-B′ perspective cross section of FIG. 1A, and FIG. 2B shows a C-C′ perspective cross section of FIG. 1A.

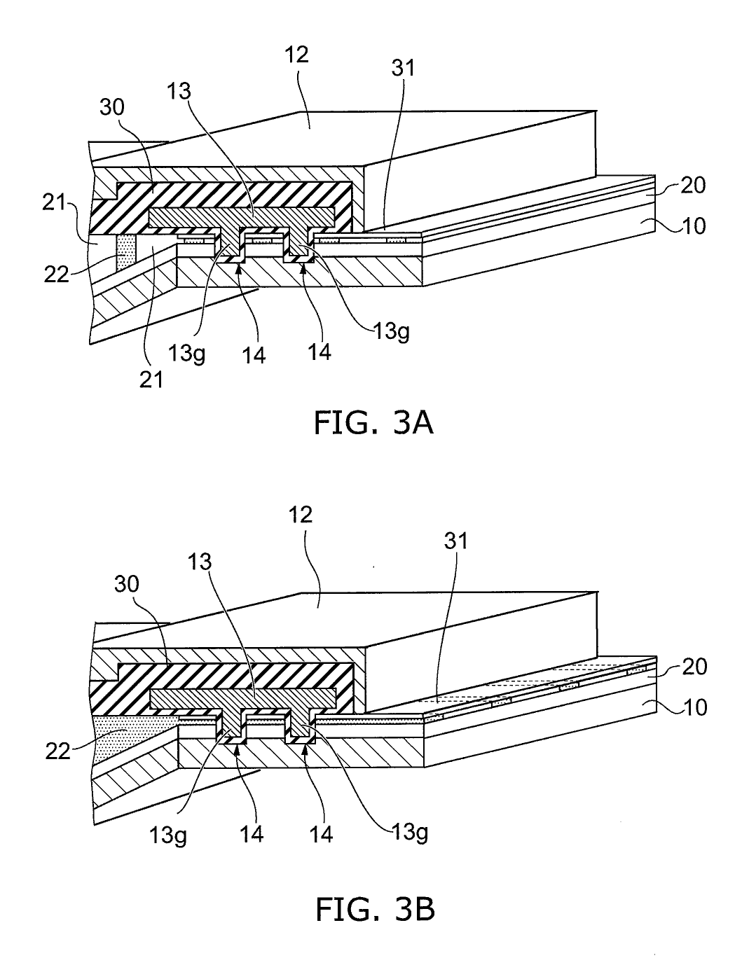

FIG. 3A shows an enlarged view of the chip terminal portion it of FIG. 1B, and FIG. 3B shows an enlarged view of the chip terminal portion it of FIG. 2A.

It is noted that FIG. 1A shows only the super junction structure portion of the semiconductor device 1 according to this embodiment. Hence, FIG. 1A does not show main electrodes, gate electrodes and the like of the semiconductor device 1. Furthermore, in this embodiment, the B-B′ direction (or C-C′ direction) of FIG. 1A is defined as the first direction, and the A-A′ direction is defined as the second direction.

The structure of the semiconductor device 1 is described with reference to these FIGS. 1A to 3B.

The semiconductor device 1 is a vertical power MOSFET element, and a main current path is formed in the vertical direction connecting between a first main electrode (drain electrode 10) and a second main electrode (source electrode 11) which are provided, respectively, on the back side and front side of the semiconductor layer. The semiconductor device 1 includes a cell region 1c in which the main current path is formed, and a chip terminal portion it formed around this cell region 1c.

Specifically, the semiconductor device 1 includes a drain layer (first-conductivity-type semiconductor layer) 20 made of n⁺-type silicon (Si) with high impurity concentration. Above the major surface of the drain layer 20, for instance, n-type pillar regions (first-conductivity-type semiconductor pillar regions) 21 made of n-type silicon and p-type pillar regions (second-conductivity-type semiconductor pillar regions) 22 made of p-type silicon are formed.

Here, the n-type pillar regions 21 and the p-type pillar regions 22 are arranged in a direction (lateral direction) generally parallel to the major surface of the drain layer 20 so as to be alternately adjacent to each other. The n-type pillar region 21 and the p-type pillar region 22 are each shaped like a stripe. The p-type pillar region 22 in the longitudinal direction (B-B′ direction) and the n-type pillar region 21 in the longitudinal direction (C-C′ direction) extend to the chip terminal portion it of the semiconductor device 1 (see, e.g., FIGS. 2A and 2B).

That is, a super junction structure with pn junctions periodically arranged therein is formed entirely above the major surface of the drain layer 20 including the cell region 1c and the chip terminal portion 1t. The n-type pillar region 21 extends also below the super junction structure and is in contact with the drain layer 20. Thus, the n-type pillar region 21 constitutes part of the main current path at on-time.

However, in the semiconductor device 1, in the direction from the middle of the chip terminal portion it toward the outside of the semiconductor device 1, the bottom of the drain layer 20 and the drain electrode 10 is raised. For instance, the semiconductor device 1 includes a slant region 1s in which the drain layer 20 and the drain electrode 10 gradually approach the front side (source electrode 11 side) of the semiconductor device 1 from the middle of the chip terminal portion it toward the outside of the semiconductor device 1. Further outside the slant region 1s, the semiconductor device 1 includes a thin layer region (MOS formation region) 1tl in which its thickness (thickness in a direction generally perpendicular to the major surface of the super junction structure) is made thinner than the super junction structure of the cell region 1c. The cell region 1c and part of the chip terminal portion it of the semiconductor device 1 are configured so as to be surrounded by the thin layer region 1tl via the slant region 1s.

In the cell region 1c of the semiconductor device 1, a base region (second-conductivity-type semiconductor region) 23 made of p-type silicon, for instance, is provided on the p-type pillar region 22. That is, the p-type pillar region 22 is connected to the base region 23. The base region 23 forms a pn junction also with the n-type pillar region 21. A source region (first-conductivity-type semiconductor region) 24 made of n⁺-type silicon, for instance, is selectively provided in part of the surface layer of the base region 23.

Furthermore, the semiconductor device 1 includes a gate electrode (trench gate electrode) 25 between the adjacent base regions 23. The lower end of the gate electrode (control electrode) 25 is located below the bottom surface of the base region 23. This gate electrode 25 serves to control a current path between the source region 24 and the n-type pillar region 21. Furthermore, a gate insulating film 26 is provided on the portion extending from the n-type pillar region 21 around the base region 23 via the base region 23 to the source region 24. This gate insulating film 26 serves to maintain insulation of the gate electrode 25 from the base region 23 and the n-type pillar region 21. Here, the material of the gate electrode 25 is illustratively polysilicon. The material of the gate insulating film 26 is illustratively silicon oxide film (SiO₂).

Furthermore, the semiconductor device 1 includes a source electrode 11 on the source region 24 and on the base region 23 between the source regions 24. That is, the source electrode 11 is electrically connected to the source region 24 and the base region 23.

Furthermore, as described above, the drain electrode 10 is provided on the surface opposite to the major surface of the drain layer 20 and is electrically connected to the drain layer 20.

Furthermore, in the semiconductor device 1, an insulating film 30 is formed on the super junction structure in the region where the base region 23 is not formed. That is, the insulating film 30 is formed on the upper side of the n-type pillar regions 21 and the upper side of the p-type pillar regions 22 in the region where the base region 23 is not formed. In the cell region 1c of the semiconductor device 1, a field plate electrode 11fa extended from the source electrode 11 is provided on the insulating film 30. Another field plate electrode 11fb is formed in the insulating film 30 below the field plate electrode 11fa (on the drain electrode 10 side).

This field plate electrode 11fb may be electrically connected to the gate electrode 25 (see, e.g., FIG. 2B). This can serve to reduce the internal gate resistance. Furthermore, in order to reduce the internal gate resistance, the field plate electrode 11fa may be separated from the source electrode 11, and the separated field plate electrode 11fa may be brought into continuity with the field plate electrode 11fb. Alternatively, the field plate electrode 11fb may itself be placed at an electrically floating potential.

Furthermore, as described above, the semiconductor device 1 has a super junction structure also in the chip terminal portion it. A first channel stop electrode 12 is provided on the insulating film 30 of the chip terminal portion it. This channel stop electrode 12 is shaped like a ring in the plane of the semiconductor device 1 and is equipotential. The channel stop electrode 12 may be electrically connected to the drain electrode 10, or may itself be placed at a floating potential. The material thereof is illustratively metal.

Furthermore, the semiconductor device 1 includes a MOS structure below the channel stop electrode 12.

For instance, a second channel stop electrode 13 is provided via the insulating film 30 below the channel stop electrode 12. A trench (trench groove) 14 is formed from the semiconductor layer (super junction structure portion) to the drain electrode 10 of the thin layer region 1tl. That is, the bottom of the trench 14 reaches the drain electrode 10. An electrode (conductive member) 13g extends from the channel stop electrode 13 into this trench 14. The insulating film 30 is formed between the electrode 13g and the inner wall of the trench 14 (see, e.g., FIGS. 3A and 3B).

By providing such a MOS structure in the thin layer region 1tl, the p-type pillar region 22 of the thin layer region 1tl is divided (cut) into a plurality by the trench 14. Thus, the p-type pillar region 22 electrically connected to the base region 23 has a structure discontinued in its longitudinal direction before the trench 14.

Like the channel stop electrode 12, the channel stop electrode 13 is shaped like a ring in the plane of the semiconductor device 1. The channel stop electrode 13 may be electrically connected to the channel stop electrode 12, or connected to the drain electrode 10. Alternatively, the channel stop electrode 13 may itself be placed at a floating potential. Here, the material of the channel stop electrode 13 is polysilicon or metal. The channel stop electrode 13 is configured so as to surround the cell region 1c and part of the chip terminal portion it of the semiconductor device 1.

Furthermore, in the thin layer region 1tl of the semiconductor device 1, an n⁺-layer region 31 is provided on the super junction structure to reduce the contact resistance between the channel stop electrode 12 and the n-type pillar region 21. This serves to stabilize the potential of the channel stop electrode 12.

Here, the dashed plane illustrated outside the semiconductor device 1 is a dicing line 40 of the semiconductor device 1 (see, e.g., FIGS. 1A to 2B).

Thus, the semiconductor device 1 includes the drain layer 20, a plurality of the n-type pillar regions 21 provided entirely and periodically above the major surface of the drain layer 20, and a plurality of the p-type pillar regions 22 being adjacent to the n-type pillar regions 21 and provided entirely and periodically above the major surface of the drain layer 20.

Furthermore, the semiconductor device 1 includes the base region 23 provided on the p-type pillar region 22, the source region 24 selectively provided in the surface of the base region 23, the drain electrode 10 connected to the drain layer 20, the source electrode 11 electrically connected to the base region 23 and the source region 24, and the gate electrode 25 for controlling the current path between the source region 24 and the n-type pillar region 21.

Furthermore, the n-type pillar regions 21 and the p-type pillar regions 22 form a super junction structure alternately repeating generally parallel to the major surface of the drain layer 20. Here, the cell region 1c includes the n-type source region 24, the p-type base region 23, and the gate electrode 25. This cell region 1c is surrounded by the chip terminal portion it. The p-type pillar region 22 electrically connected to the base region 23 and extending generally perpendicular to the alternately repeating direction of the super junction structure extends from the chip region 1c to the chip terminal portion it and is discontinued in the thin layer region 1tl of the chip terminal portion it (end region of the chip terminal portion 1t) by the trench 14.

Next, the function and effect of the semiconductor device 1 are described.

First, in the semiconductor device 1, a voltage is applied with the drain electrode 10 being a positive electrode and the source electrode 11 being a negative electrode or placed at the ground potential. In this state, when the gate electrode 25 is placed at the same potential as the source electrode 11, the base region 23 between the source region 24 and the n-type pillar region 21 is depleted, and the semiconductor device 1 is turned off.

At this time, the depletion layer extends also from the pn junction interface between the p-type pillar region 22 electrically connected to the source electrode 11 and the n-type pillar region 21 adjacent to this p-type pillar region 22, and the depletion layer extends into the p-type pillar region 22 and the n-type pillar region 21 below the source electrode 11.

Furthermore, because the semiconductor device 1 includes the field plate electrodes 11fa, 11fb, a depletion layer is formed also in the p-type pillar region 22 and the n-type pillar region 21 below the field plate electrode 11fa, and this depletion layer is connected to the depletion layer formed below the source electrode 11. Thus, the semiconductor layer below the source electrode 11 and below the field plate electrodes 11fa, 11fb is entirely depleted. This alleviates the electric field at the end of the outermost base region 23 and on the surface of the semiconductor layer below the field plate electrodes 11fa, 11fb where the electric field is likely to concentrate. Consequently, the semiconductor device 1 maintains a high breakdown voltage despite high voltage applied between the main electrodes.

Furthermore, in this embodiment, the p-type pillar region 22 of the thin layer region 1tl is divided by the trench 14. This results in a configuration in which the p-type pillar region 22 electrically connected to the source electrode 11 is electrically blocked before the trench 14. That is, in the semiconductor device 1, the side surface of the n-type pillar region 21 electrically connected to the drain electrode 10 is exposed at the dicing line 40. Furthermore, the p-type pillar region 22 electrically connected to the source electrode 11 is divided by the trench 14 in the end region of the chip terminal portion it and does not reach the dicing line 40. That is, the p-type pillar region 22 provided in the cell region 1c is electrically insulated from the p-type pillar region 22 provided at the end of the chip terminal portion 1t.

In contrast, without the trench 14, the p-type pillar region 22 electrically connected to the source electrode 11 and the n-type pillar region 21 electrically connected to the drain electrode 10 are exposed at the dicing line 40. In this state, if a voltage is applied between the main electrodes, the depletion layer reaches the dicing line 40 and results in chip damage near the dicing line 40 and variation in the breakdown voltage of the semiconductor device 1. Furthermore, leakage may occur in the chip end portion. Moreover, reliability tests of the semiconductor device 1 may fail to accurately reflect its proper characteristics.

However, the semiconductor device 1 has a structure in which the p-type pillar region 22 electrically connected to the source electrode 11 is blocked before the trench 14. In such a structure, extension of the depletion layer from the cell region 1c can be reliably stopped before the trench 14. That is, the aforementioned damage, breakdown voltage variation, and leakage are suppressed, and reliability tests of the semiconductor device 1 accurately reflect its proper characteristics.

Furthermore, in the semiconductor device 1, the channel stop electrodes 12, 13 are provided in the chip terminal portion 1t. By equalizing the potential of the channel stop electrodes 12, 13 with that of the drain layer 20, or placing them at a floating potential, the gradient of the electric field near the chip end portion is further relaxed. This further prevents the depletion layer from reaching the thin layer region 1tl.

On the other hand, when a positive potential is applied to the gate electrode 25, a channel layer is formed near the surface of the base region 23, allowing conduction between the source region 24 and the n-type pillar region 21. That is, the semiconductor device 1 is turned on.

Next, a process for manufacturing the semiconductor device 1 is described.

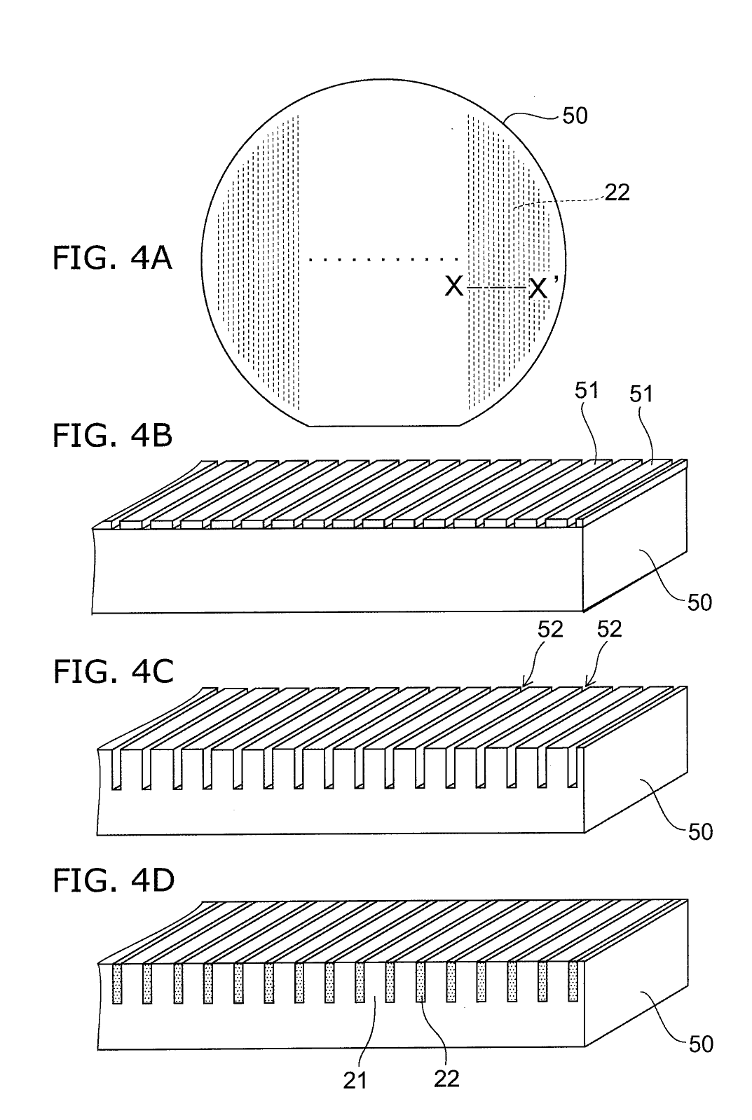

FIGS. 4A to 6C are principal views illustrating the process for manufacturing a semiconductor device.

First, as shown in FIG. 4A, the n-type pillar regions 21 and the p-type pillar regions 22 with a uniform width in a striped configuration are alternately formed in the entire surface of a wafer-shaped semiconductor substrate 50.

The process for forming the n-type pillar regions 21 and the p-type pillar regions 22 is described in more detail with reference to the X-X′ cross section of FIG. 4A.

For instance, the n-type semiconductor substrate 50 is prepared. Then, as shown in FIG. 4B, a line-and-space photoresist 51 is patterned on this semiconductor substrate 50. The opening width of this photoresist 51 is made constant throughout the semiconductor substrate 50.

Next, as shown in FIG. 4C, RIE (reactive ion etching) is performed on the semiconductor substrate 50 to form trenches 52 in the surface of the semiconductor substrate 50. The photoresist 51 is removed after the trenches 52 are formed.

Then, as shown in FIG. 4D, the p-type pillar region 22 is formed in the trench 52 by epitaxial growth. Furthermore, the upper surface of the n-type pillar regions 21 and the p-type pillar regions 22 is planarized illustratively by CMP polishing.

By such a process, a super junction structure is formed in which the n-type pillar regions 21 and the p-type pillar regions 22 are alternately repeated in a direction generally parallel to the major surface of the semiconductor substrate 50.

Next, chip areas (semiconductor chip regions) are defined in the region of the semiconductor substrate 50 where the n-type pillar regions 21 and the p-type pillar regions 22 are alternately formed. The size of the chip area is arbitrary. Then, a MOS gate manufacturing process is performed on the region of each partitioned chip area in which a current is to be passed between the main electrodes (between the drain electrode 10 and the source electrode 11). For instance, the base region 23 is formed on the p-type pillar region 22 of the aforementioned region. The source region 24 is selectively formed in the base region 23. The gate electrode 25 is formed between the base regions 23 via the gate insulating film 26.

Furthermore, the insulating film 30 is formed on the super junction structure where the base region 23 is not placed. Furthermore, the source electrode 11 is formed on the base region 23 and the source region 24. Here, the field plate electrode 11fa is extended from the source electrode 11. Furthermore, before the field plate electrode 11fa is formed, the field plate electrode 11fb is formed in the insulating film 30 below the field plate electrode 11fa.

In this embodiment, when the aforementioned MOS gate manufacturing process is performed, a MOS structure is formed also in the thin layer region 1tl. For instance, after the trench 14 is formed in the thin layer region 1tl, the electrode 13g (channel stop electrode 13) is formed in this trench 14 via the insulating film 30. That is, the channel stop electrode 13, the trench 14 and the like have a configuration similar to that of the MOS gate electrode, and hence these are formed in the same process. Furthermore, the channel stop electrode 12 is formed on the channel stop electrode 13 via the insulating film 30.

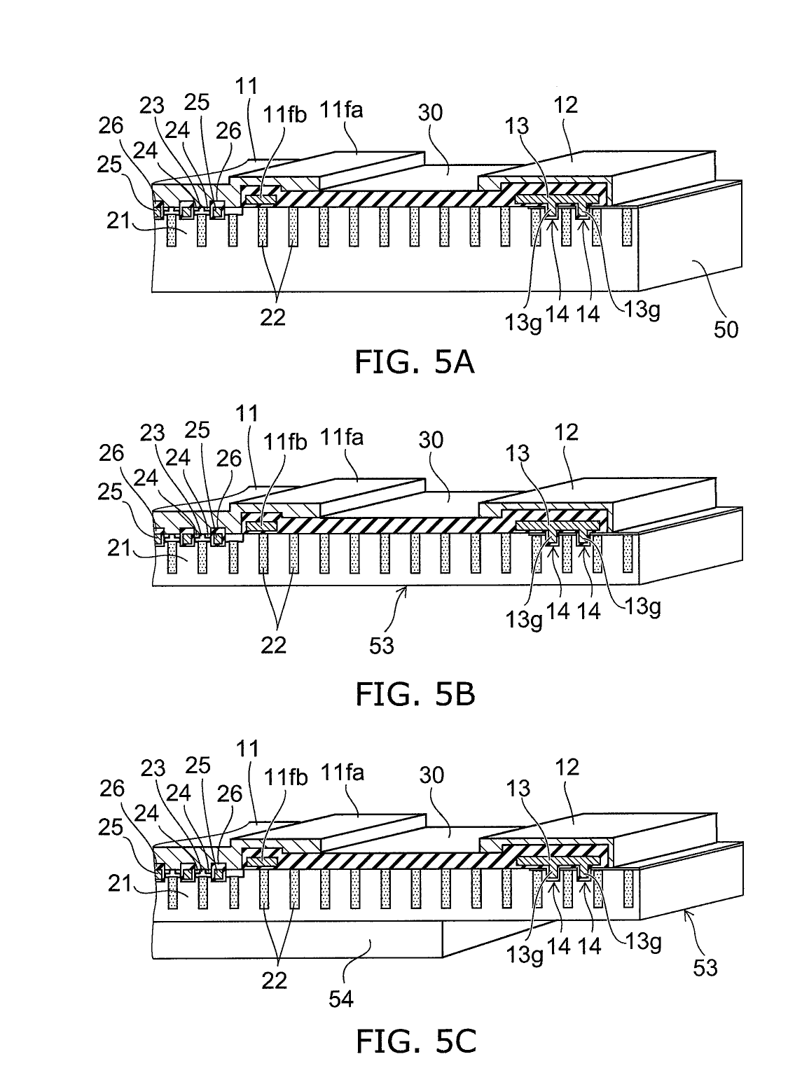

This state is shown in FIG. 5A.

Next, as shown in FIG. 5B, the back side of the semiconductor substrate 50 is polished so as to leave the super junction structure throughout the semiconductor substrate 50. The surface polished in this stage is referred to as a first polished surface (exposed surface) 53. The polishing means is illustratively based on CMP, etching and the like.

Next, as shown in FIG. 5C, a resist 54 is selectively formed on the polished surface 53 of each chip. For instance, the resist 54 is formed on the cell region 1c, and also formed on the chip terminal portion it except the slant region 1s and the thin layer region 1tl.

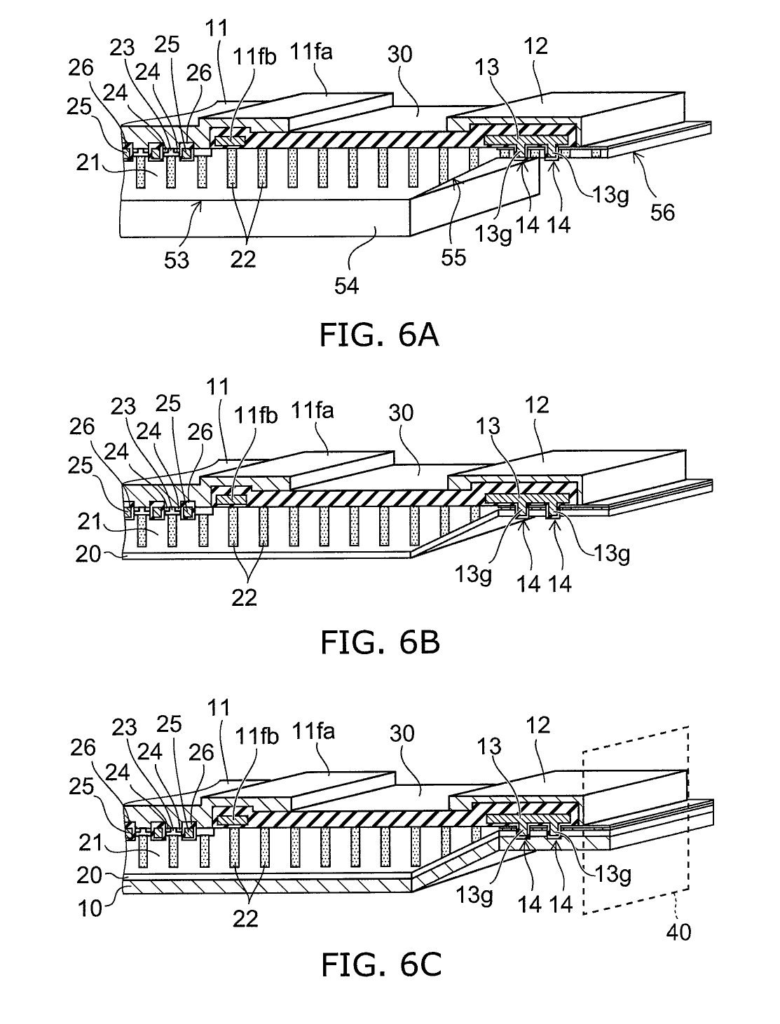

Next, as shown in FIG. 6A, etching processing is performed on the polished surface 53 exposed from the resist 54. For instance, in the slant region 1s, the super junction structure is obliquely etched to form a second exposed surface 55 on the back side of the semiconductor substrate 50. In the thin layer region 1tl, the super junction structure is etched generally parallel to the polished surface 53 to form a third exposed surface 56 on the back side of the semiconductor substrate 50. Thus, the back side of the semiconductor substrate 50 is configured so that the polished surface 53, the slant exposed surface 55, and the exposed surface 56 are continuously formed. In the thin layer region 1tl, the bottom of the exposed surface 56 is raised from the polished surface 53. That is, part of the chip terminal portion it of the semiconductor chip region is turned into a thin layer. Here, the etching is illustratively based on wet etching using an alkaline aqueous solution (KOH solution).

Next, the resist 54 is removed. Then, as shown in FIG. 6B, a drain layer 20 is formed on the polished surface 53 and the exposed surfaces 55, 56. The drain layer 20 is formed illustratively by performing ion implantation and solid-phase diffusion (heating treatment, laser annealing etc.) on the polished surface 53 and the exposed surfaces 55, 56.

By such a process, the p-type pillar region 22 electrically connected to the base region 23 and extending generally perpendicular to the alternately repeating direction of the super junction structure is partly removed in the chip terminal portion it and results in a configuration which does not reach the end portion (dicing line 40) of the chip area (see FIG. 2A). In other words, the p-type pillar region 22 electrically connected to the base region 23 is configured so as not to continue to the end portion of the semiconductor chip region.

Then, as shown in FIG. 6C, a drain electrode 10 is formed on the drain layer 20. Subsequently, the semiconductor substrate 50 is cut along the dicing line 40. This results in a semiconductor device 1 singulated from the semiconductor substrate 50.

In this embodiment, the thickness of the drain layer 20 is 10 μm or less so that solid-phase diffusion for forming the drain layer 20 can be rapidly performed. The exposed surface 55 is formed as a gradual slope. Consequently, in the ion implantation process, impurity is efficiently implanted into the polished surface 53 and the exposed surfaces 55, 56, and the drain layer 20 with uniform impurity concentration is formed.

Furthermore, in this embodiment, to facilitate the wafer process for the front side and back side of the semiconductor substrate 50, markings may be provided on the front side and back side of the semiconductor substrate 50 so as to enable matching of positions (alignment) between the front side and back side of the semiconductor substrate 50.

In such a manufacturing method, an arbitrary chip size can be defined even after the super junction structure is formed in the semiconductor substrate 50. Hence, the chip size of the semiconductor device 1 can be easily changed.

Hence, even if the chip size is changed with the market trend, the method can quickly respond to the change. For instance, it is possible to easily switch between the chip size requiring mass production and the chip size only requiring low-volume production. This prevents dead stock of devices only requiring low-volume production. Furthermore, in semiconductor devices manufactured with any chip size, the p-type pillar region 22 electrically connected to the source electrode 11 is always blocked before the trench 14. Thus, in every chip size, highly reliable semiconductor devices are formed.

In contrast, in a structure in which a high resistance layer is placed near the dicing line, or in which the width of the super junction structure is varied between the internal region of the chip and the neighborhood of the dicing line, it is difficult to change the chip size in the middle of the wafer process. For instance, once a super junction structure is formed in the semiconductor substrate 50, it is difficult to change that portion to a high resistance layer, or to change its width, in response to a request for changing the chip size.

Furthermore, this embodiment has no problem if a large amount of semiconductor substrates 50 with the super junction structure are manufactured beforehand in a separate process. Furthermore, because the semiconductor device 1 can be manufactured from the semiconductor substrate 50 with the super junction structure provided beforehand, the process for layers above the super junction structure is rate-limiting in the process for manufacturing the semiconductor device 1. This serves to shorten the process for manufacturing the semiconductor device.

Furthermore, according to this embodiment, there is no need to form super junction structures with different widths in the plane of the semiconductor device 1 or in the semiconductor substrate 50.

For instance, in the case where super junction structures with different pillar widths are needed in a chip, it is necessary to form trenches with different widths in the semiconductor substrate 50. To this end, a resist pattern with different pattern pitches needs to be formed on the semiconductor substrate 50 to proceed with the wafer process.

However, the resist pattern with different pitches is susceptible to the expansion ratio dependence of resist volume at the time of resist baking. Thus, depending on the position of the semiconductor substrate 50, the opening width may be different from the intended opening width. To prevent this, it is necessary to design a special exposure mask by allowing for the expansion ratio dependence of the resist for each position.

However, in this embodiment, it is only necessary to form the semiconductor substrate 50 having a super junction structure with a uniform width. Hence, time and effort for designing the exposure mask as described above can be saved. This serves to reduce the cost of the semiconductor device.

Furthermore, when the super junction structure is formed, if the trench opening width varies in the chip, as the trench opening width becomes narrower, voids are more likely to occur in the p-type pillar region 22 in the epitaxial process for the p-type pillar region 22. Furthermore, the wafer outer periphery of the semiconductor substrate 50 may include various surface orientations. Hence, in the outer periphery of the semiconductor substrate 50, voids are likely to occur in the p-type pillar region 22 due to the surface orientation dependence of the epitaxial growth rate of the p-type pillar region 22.

However, in this embodiment, a super junction structure with a uniform width is formed in the entire surface of the semiconductor substrate 50, and only this portion is used for device formation. The outer peripheral portion of the semiconductor substrate 50 is not used for device formation. This results in a super junction structure in which void generation is suppressed.

Thus, according to this embodiment, the productivity of semiconductor devices is improved, and a highly reliable semiconductor device is realized.

Next, variations of the semiconductor device are described. In the following figures, the same members as those in FIGS. 1A to 6C are labeled with like reference numerals, and the detailed description thereof is omitted as appropriate.

### Second Embodiment

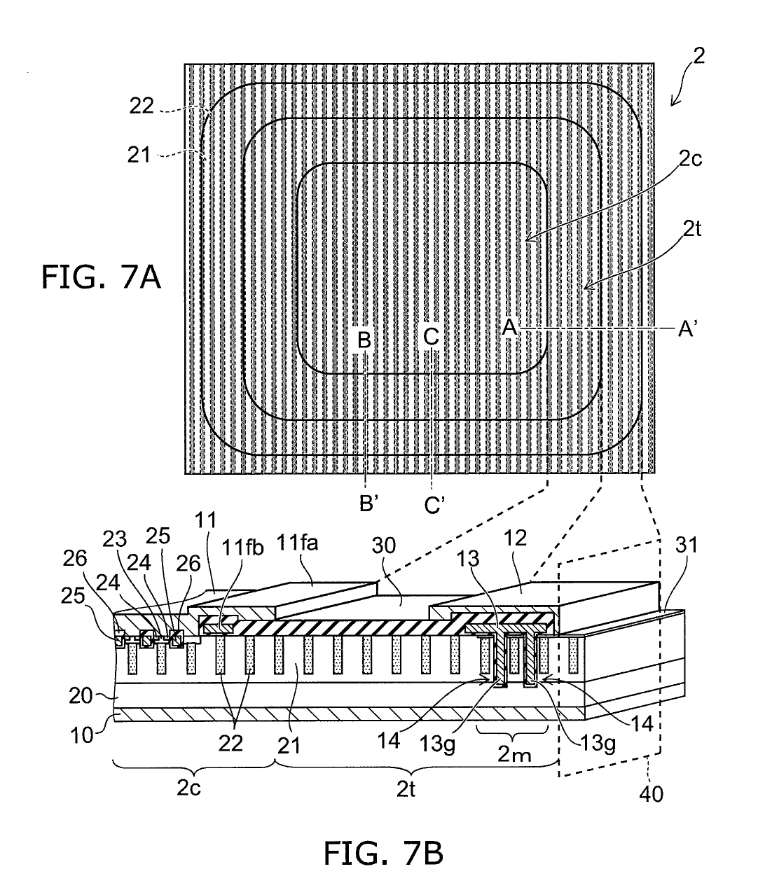

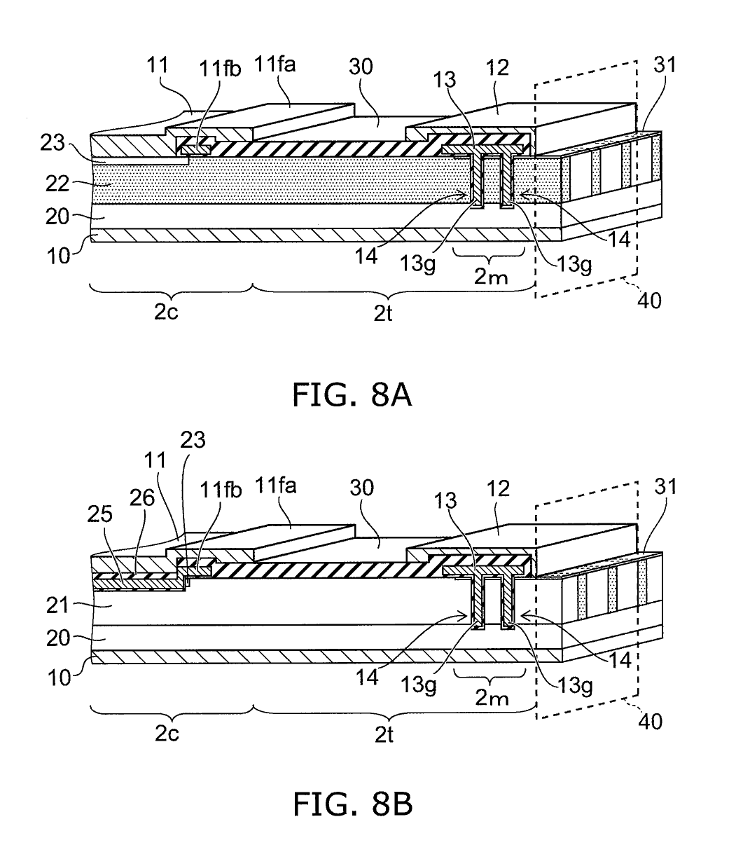

FIGS. 7A to 8B are principal views of a semiconductor device. Here, FIG. 7A is a principal plan view of the semiconductor device, and FIG. 7B shows an A-A′ perspective cross section of FIG. 7A. FIG. 8A shows a B-B′ perspective cross section of FIG. 7A, and FIG. 8B shows a C-C′ perspective cross section of FIG. 7A. It is noted that FIG. 7A shows only the super junction structure portion of a semiconductor device 2 according to this embodiment. Furthermore, the B-B′ direction (or C-C′ direction) of FIG. 7A is defined as the first direction, and the A-A′ direction is defined as the second direction.

The structure of the semiconductor device 2 is described with reference to these FIGS. 7A to 8B.

The semiconductor device 2 is a vertical power MOSFET element, and includes a cell region 2c in which the main current path is formed, and a chip terminal portion 2t formed around this cell region 2c.

Specifically, the semiconductor device 2 includes the drain layer 20 made of n⁺-type silicon with high impurity concentration. Above the major surface of the drain layer 20, for instance, the n-type pillar regions 21 made of n-type silicon and the p-type pillar regions 22 made of p-type silicon are formed. The p-type pillar region 22 (or n-type pillar region 21) in the longitudinal direction (B-B′ direction) extends to the chip terminal portion 2t of the semiconductor device 2. That is, a super junction structure with pn junctions periodically arranged therein is formed entirely above the major surface of the drain layer 20 including the cell region 2c and the chip terminal portion 2t.

Furthermore, in the semiconductor device 2, the insulating film 30 is formed on the super junction structure in the region where the base region 23 is not formed. The channel stop electrode 12 is provided on the insulating film 30 of the chip terminal portion 2t. This channel stop electrode 12 is shaped like a ring in the plane of the semiconductor device 2 and is equipotential. Furthermore, the semiconductor device 2 includes a MOS structure below the channel stop electrode 12. This region is referred to as a MOS formation region 2m.

For instance, the channel stop electrode 13 is provided via the insulating film 30 below the channel stop electrode 12. The trench 14 is formed from the semiconductor layer (super junction structure portion) to the drain electrode 20 of the MOS formation region 2m. That is, the bottom of the trench 14 reaches the drain electrode 20. The electrode 13g extends from the channel stop electrode 13 into this trench 14. The insulating film 30 is formed between the electrode 13g and the inner wall of the trench 14.

By providing such a MOS structure in the semiconductor device 2, the p-type pillar region 22 of the MOS formation region 2m is divided (cut) into a plurality by the trench 14 (see, e.g., FIG. 8A). Thus, the p-type pillar region 22 electrically connected to the base region 23 has a structure discontinued in its longitudinal direction before the trench 14. In the semiconductor device 2 like this, the side surface of the n-type pillar region 21 electrically connected to the drain electrode 10 is exposed at the dicing line 40. Furthermore, the p-type pillar region 22 electrically connected to the source electrode 11 is divided (discontinued) by the trench 14 in the MOS formation region 2m (end region of the chip terminal portion 2t) and does not reach the dicing line 40.

In such a structure, even if a high voltage is applied between the main electrodes, extension of the depletion layer from the cell region 2c can be reliably stopped before the trench 14. Furthermore, by equalizing the potential of the channel stop electrodes 12, 13 with that of the drain layer 20, or placing them at a floating potential, the gradient of the electric field near the chip end portion is further relaxed. This further prevents the depletion layer from reaching the MOS formation region 2m. That is, like the semiconductor device 1, the semiconductor device 2 is resistant to damage near the dicing line 40 and variation in breakdown voltage. Furthermore, no leakage occurs in the chip end portion. Moreover, reliability tests of the semiconductor device 2 accurately reflect its proper characteristics.

Furthermore, also in the manufacturing of the semiconductor device 2, it is possible to use the semiconductor substrate 50 with a super junction structure formed throughout the wafer surface. Hence, an arbitrary chip size can be defined even after the super junction structure is formed in the semiconductor substrate 50. That is, the chip size can be easily changed in the semiconductor device 2.

Furthermore, this embodiment has no problem if a large amount of semiconductor substrates 50 with the super junction structure are manufactured beforehand in a separate process. Furthermore, the process for layers above the super junction structure is rate-limiting in the process for manufacturing the semiconductor device 2. This serves to shorten the process for manufacturing the semiconductor device.

Furthermore, according to this embodiment, there is no need to form super junction structures with different widths in the plane of the semiconductor device 2 or in the semiconductor substrate 50. Hence, time and effort for designing the exposure mask as described above can be saved. This serves to reduce the cost of the semiconductor device.

Furthermore, in this embodiment, a super junction structure with a uniform width is formed in the entire surface of the semiconductor substrate 50, and only this portion is used for device formation. The outer peripheral portion of the semiconductor substrate 50 is not used for device formation. This results in, as described above, a super junction structure in which void generation is suppressed.

Thus, according to this embodiment, the productivity of semiconductor devices is improved, and a highly reliable semiconductor device is realized.

### Third Embodiment

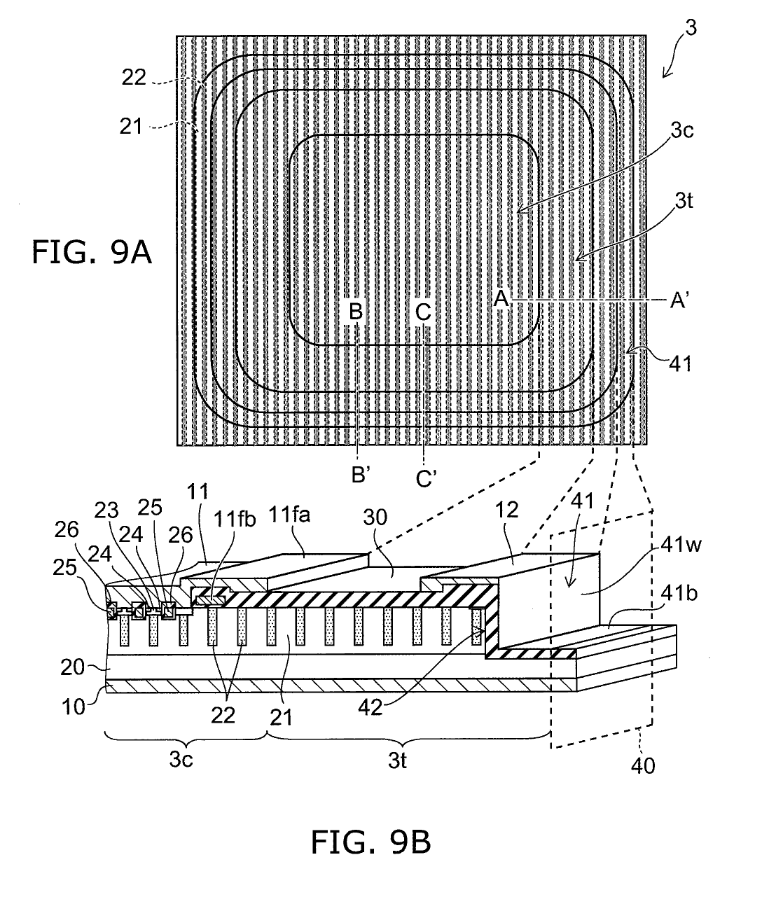

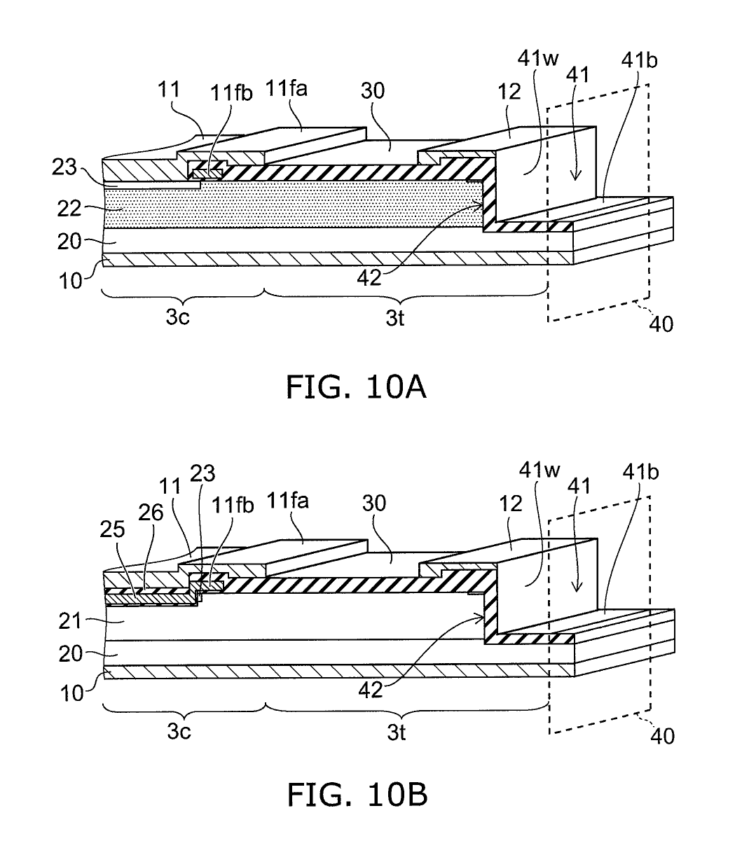

FIGS. 9A to 10B are principal views of a semiconductor device. Here, FIG. 9A is a principal plan view of the semiconductor device, and FIG. 9B shows an A-A′ perspective cross section of FIG. 9A. FIG. 10A shows a B-B′ perspective cross section of FIG. 9A, and FIG. 10B shows a C-C′ perspective cross section of FIG. 9A. It is noted that FIG. 9A shows only the super junction structure portion of a semiconductor device 3 according to this embodiment. Furthermore, the B-B′ direction (or C-C′ direction) of FIG. 9A is defined as the first direction, and the A-A′ direction is defined as the second direction.

The semiconductor device 3 is a vertical power MOSFET element, and includes a cell region 3c in which the main current path is formed, and a chip terminal portion 3t formed around this cell region 3c.

Specifically, the semiconductor device 3 includes the drain layer 20 made of n⁺-type silicon with high impurity concentration. Above the major surface of the drain layer 20, for instance, the n-type pillar regions 21 made of n-type silicon and the p-type pillar regions 22 made of p-type silicon are formed. The p-type pillar region 22 (or n-type pillar region 21) in the longitudinal direction (B-B′ direction) extends to the chip terminal portion 3t of the semiconductor device 3. That is, a super junction structure with pn junctions periodically arranged therein is formed entirely above the major surface of the drain layer 20 including the cell region 3c and the chip terminal portion 3t.

Furthermore, in the semiconductor device 3, the insulating film 30 is formed on the super junction structure in the region where the base region 23 is not formed. The channel stop electrode 12 is provided on the insulating film 30 of the chip terminal portion 3t. This channel stop electrode 12 is shaped like a ring in the plane of the semiconductor device 3 and is equipotential. Furthermore, the semiconductor device 3 includes a groove-shaped recess 41 inside the dicing line 40. The recess 41 is formed illustratively by etching. To a side surface 41w of the recess 41, the channel stop electrode 12 and the insulating film 30 are exposed. To a bottom surface 41b of the recess 41, the insulating film 30 is exposed. The insulating film 30 formed at the bottom surface 41b of the recess 41 is in contact with the drain layer 20 in the chip terminal portion 3t.

By providing the recess 41 in the semiconductor device 3, the p-type pillar region 22 electrically connected to the base region 23 has a structure blocked in its longitudinal direction by the insulating film 30 provided at the side surface of the recess 41. That is, the p-type pillar region 22 is discontinued by the recess 41 provided on the end portion of the drain electrode 10 in the chip terminal portion 3t.

That is, in the chip terminal portion 3t surrounding the cell region 3c of the semiconductor device 3, a longitudinal end surface 42 of the p-type pillar region 22 and the n-type pillar region 21 connected to the base region 23 and extending generally perpendicular to the alternately repeating direction of the n-type pillar regions 21 and the p-type pillar regions 22 is set back from the end portion (dicing line 40) of the chip terminal portion 3t toward the cell region 3c as shown in FIGS. 10A and 10B. Furthermore, the end surface 42 of the p-type pillar region 22 and the n-type pillar region 21 is covered with the insulating film 30. Thus, the p-type pillar region 22 and the n-type pillar region 21 have a structure discontinued in the end region of the chip terminal portion 3t.

In such a structure, even if a high voltage is applied between the main electrodes, extension of the depletion layer from the cell region 3c can be reliably stopped before the insulating film 30 provided at the side surface of the recess 41. Furthermore, by equalizing the potential of the channel stop electrode 12 with that of the drain layer 20, or placing them at a floating potential, the gradient of the electric field near the chip end portion is further relaxed. This further prevents the depletion layer from reaching near the recess 41. That is, like the semiconductor device 1, the semiconductor device 3 is resistant to damage near the dicing line 40 and variation in breakdown voltage. Furthermore, no leakage occurs in the chip end portion.

In particular, in the semiconductor device 3, the longitudinal end surface 42 of the p-type pillar region 22 and the n-type pillar region 21 extending generally perpendicular to the alternately repeating direction of the n-type pillar regions 21 and the p-type pillar regions 22 is set back from the dicing line 40 toward the cell region 3c as shown in FIGS. 10A and 10B. Furthermore, the end surface 42 of the p-type pillar region 22 and the n-type pillar region 21 is covered with the insulating film 30. In such a structure, even if the semiconductor substrate 50 is cut along the dicing line 40, the surface of the insulating film 30 covering each end surface 42 does not constitute the cutting surface, and no defects (cracks) occur in the insulating film 30. Thus, the insulating film 30 covering the end surface 42 of the p-type pillar region 22 and the n-type pillar region 21 can maintain a high breakdown voltage. Consequently, reliability tests of the semiconductor device 3 accurately reflect its proper characteristics.

Furthermore, also in the manufacturing of the semiconductor device 3, it is possible to use the semiconductor substrate 50 with a super junction structure formed throughout the wafer surface. Hence, an arbitrary chip size can be defined even after the super junction structure is formed in the semiconductor substrate 50. That is, the chip size can be easily changed in the semiconductor device 3.

Furthermore, this embodiment has no problem if a large amount of semiconductor substrates 50 with the super junction structure are manufactured beforehand in a separate process. Furthermore, the process for layers above the super junction structure is rate-limiting in the process for manufacturing the semiconductor device 3. This serves to shorten the process for manufacturing the semiconductor device.

Furthermore, according to this embodiment, there is no need to form super junction structures with different widths in the plane of the semiconductor device 3 or in the semiconductor substrate 50. Hence, time and effort for designing the exposure mask as described above can be saved. This serves to reduce the cost of the semiconductor device.

Furthermore, in this embodiment, a super junction structure with a uniform width is formed in the entire surface of the semiconductor substrate 50, and only this portion is used for device formation. The outer peripheral portion of the semiconductor substrate 50 is not used for device formation. This results in, as described above, a super junction structure in which void generation is suppressed.

Thus, according to this embodiment, the productivity of semiconductor devices is improved, and a highly reliable semiconductor device is realized.

Various components of the above examples and their layout, material, condition, shape, size and the like are not limited to those illustrated, but can be suitably modified.

Furthermore, various components of the above embodiments can be combined with each other as long as technically feasible, and such combinations are also encompassed within the scope of the invention as long as they fall within the spirit of the invention.

For instance, the process for forming the super junction structure is not limited to the aforementioned methods. Specifically, the present embodiments also include a formation process including crystal growth of a high resistance semiconductor layer on the major surface of the drain layer 20, and ion implantation of p-type dopant and n-type dopant into the surface thereof, followed by another crystal growth of a high resistance semiconductor layer.

Furthermore, instead of the trench-shaped gate electrode 25, a planar gate electrode may be provided.

Furthermore, with regard to the trench 14 and the recess 41 described above, the effect of the invention can be achieved as long as they are provided so as to extend generally perpendicular to the alternately repeating direction of the n-type pillar regions 21 and the p-type pillar regions 22. Hence, the present embodiments also include the structure in which the trench 14 and the recess 41 are not provided in the aforementioned alternately repeating direction.

In the present embodiments, a vertical power MOSFET element is illustrated. However, they are applicable also to other switching devices such as IGBT elements. Furthermore, the semiconductor material is not limited to Si (silicon), but silicon carbide (SiC) and gallium nitride (GaN) can also be used.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A semiconductor device comprising:
a first-conductivity-type semiconductor layer;
a first-conductivity-type semiconductor pillar region and a second-conductivity-type semiconductor pillar region each extending in a first direction and alternately provided along a second direction generally perpendicular to the first direction entirely on a major surface of the first-conductivity-type semiconductor layer;
a second-conductivity-type semiconductor region provided on the second-conductivity-type semiconductor pillar region in a cell region and connected to the second-conductivity-type semiconductor pillar region;
a first-conductivity-type semiconductor region selectively provided in a surface of the second-conductivity-type semiconductor region;
a first main electrode connected to the first-conductivity-type semiconductor layer;
a second main electrode connected to the first-conductivity-type semiconductor region and the second-conductivity-type semiconductor region; and
a control electrode configured to control a current path between the first-conductivity-type semiconductor region and the first-conductivity-type semiconductor pillar region,
the cell region including the first-conductivity-type semiconductor region, the second-conductivity-type semiconductor region, and the control electrode, and
the second-conductivity-type semiconductor pillar region extending from the cell region to a chip terminal portion which surrounds the cell region, and discontinued in an end region of the chip terminal portion.

2. The device according to claim 1, wherein
the second-conductivity-type semiconductor pillar region is divided by a trench groove provided in the chip terminal portion,
a conductive member is provided in the trench groove via an insulating film, and
the second-conductivity-type semiconductor pillar region provided in the cell region is electrically insulated from the second-conductivity-type semiconductor pillar region provided at an end of the chip terminal portion.

3. The device according to claim 2, wherein bottom of the trench groove reaches the first main electrode or the first-conductivity-type semiconductor layer.

4. The device according to claim 2, wherein the conductive member is connected to the first main electrode or placed in an electrically floating state.

5. The device according to claim 1, further comprising:
an insulating film on an upper side of the first-conductivity-type semiconductor pillar region and an upper side of the second-conductivity-type semiconductor pillar region where the second-conductivity-type semiconductor region is not formed; and
a first field plate electrode extending from the second main electrode onto the insulating film.

6. The device according to claim 5, further comprising:
a second field plate electrode provided on a side of the first main electrode of the first field plate electrode.

7. The device according to claim 6, wherein the second field plate electrode is connected to the control electrode.

8. The device according to claim 1, wherein an end surface in the first direction of the first-conductivity-type semiconductor pillar region and the second-conductivity-type semiconductor pillar region is set back from a chip end in the chip terminal portion and covered with an insulating film.

9. The device according to claim 8, wherein the insulating film is connected to the first-conductivity-type semiconductor layer in the chip terminal portion.

10. The device according to claim 1, wherein thickness of the first-conductivity-type semiconductor pillar region and the second-conductivity-type semiconductor pillar region in a direction generally perpendicular to the major surface is thinner than thickness of the cell region at least in a part of the chip terminal portion.
